(19) United States
(12) Patent Application Publication
(10) Pub. No.: US 2008/0217724 A1
(43) Pub. Date: Sep. 11, 2008

(54) BACKSIDE ILLUMINATED SOLID-STATE IMAGING DEVICE

(76) Inventor: Shinji UYA, Kurokawa-gun (JP)

Correspondence Address: BIRCH STEWART KOLASCH & BIRCH, PO BOX 747, FALLS CHURCH, VA, 22040-0747, US

(21) Appl. No.: 12/032,393

(22) Filed: Feb. 15, 2008

(30) Foreign Application Priority Data
Feb. 21, 2007 (JP) P2007-040558

(51) Int. Cl. H01L 31/103

(52) U.S. Cl. 257/460; 257/E31.057

(57) ABSTRACT

A backside illuminated solid-state imaging device is provided and includes: a p-type semiconductor substrate; an imaging region that receives a subject light through a back side of the p-type semiconductor substrate to accumulate a signal corresponding to an amount of the received light; a signal reading element disposed in a front side of the p-type semiconductor substrate, the signal reading element reading out the signal from the imaging region; and an n-well region disposed in the front side of the p-type semiconductor substrate and in a periphery of the imaging region, the n-well region being biased to a positive voltage.

This application is based on and claims priority under 35 U.S.C. § 119 from Japanese Patent Application No. 2007-40558 filed Feb. 21, 2007, the entire disclosure of which is herein incorporated by reference.

### BACKGROUND OF THE INVENTION

1. Field of the Invention

The present invention relates to a backside illuminated solid-state imaging device, and particularly to a backside illuminated solid-state imaging device having a structure suitable for suppressing dark current noise from mixing to signal charges.

2. Description of Related Art

Solid-state imaging devices such as a CMOS image sensor and a CCD image sensor are classified into the front side illuminated type and the backside illuminated type. The front side illuminated type has a structure in which incident light from an object is received by the same surface as one surface side (hereinafter, this face is referred to as “front side”) of a semiconductor substrate where a signal reading circuit (in the case of a CMOS image sensor, a transistor circuit and a wiring layer, and, in the case of a CCD image sensor, a charge transfer circuit including wirings) that is a main electronic element of an image sensor is formed.

By contrast, the backside illuminated type has a structure in which, as described in JP-A-2006-32497 or the like, incident light from an object is received by a surface opposite to the front side of a semiconductor substrate where a signal reading circuit is formed, i.e., the backside surface. The backside illuminated type has advantages that the light receiving area is made wider than that of the front side illuminated type, and that the quantum efficiency is so high to be highly sensitive.

Dark current noise, which may be a problem in solid-state imaging devices, is generated in a depletion layer. Therefore, the front side illuminated type is configured so that, in order to prevent an Si/SiO₂ interface in the surface of a storage region for signal charges (for example, an n-region disposed in a semiconductor substrate) from being depleted, a high-concentration p-type diffusion layer is formed in the surface of the storage region, a metal electrode functioning also as a light blocking film is disposed so as to cover a part of the layer, and the metal electrode is grounded. Charges (activation energy: 1.12 eV) which are generated in a deep portion in the substrate are drawn to the outside by positively biasing the n-type semiconductor substrate, so that a state is attained where there is only the contribution of a thin photodiode depletion layer (2 to 3 μm) in the vicinity of the surface.

Furthermore, the front side illuminated type has a structure where holes generated together with the signal charges are moved through the high-concentration p-type diffusion layer (p-type impurity concentration: about 10¹⁹/cm³) in the surface of the photodiode and a channel stop (p-type impurity concentration: about 10¹⁷/cm³) which is an element separation region and which has a relatively high concentration, and swept away to the outside through a grounding terminal.

When the resistance for swept holes is high, the potential distribution of an imaging region where the photodiode is disposed becomes unbalanced, and characteristic differences are produced between center pixels and peripheral pixels in an effective imaging region. When many pairs of electrons and holes are generated by highlighting light, particularly, excess electrons can be easily swept away by a vertical overflow drain structure, but excess holes are swept away through the thin channel stop and the like. Therefore, the sweeping process requires a time period, and there occurs a phenomenon that an abnormal imaging state continues for a while. This state may be changed depending on the presence or absence of an operation of an electronic shutter.

By contrast, in an image sensor of the backside illuminated type, the entire interface portion of a backside oxidation film is configured by a continuous high-concentration p-layer. Accordingly, there is no concern about the sweeping of holes as far as the high-concentration p-layer is properly ground wired.

In the technique described in JP-A-2006-32497, in order to form wiring for grounding the high-concentration p-layer, through holes which penetrate through the semiconductor substrate should be formed, and a metal should be embedded into the through holes. However, it is difficult to uniformly embed the metal into the through holes having a depth of 5 to 10 μm) and hence the production cost of a backside illuminated solid-state imaging device is increased.

Also, the manner how unwanted electrons generated in the vicinity of the imaging region are blocked from entering the imaging region is a problem in an image sensor of the backside illuminated type which employs a p-type semiconductor substrate. In an image sensor of the front side illuminated type, a photoelectric converting region has a depth of 2 to 3 μm in the light incidence direction. By contrast, in an image sensor of the backside illuminated type, a photoelectric converting region is considerably thick or has a depth of 5 to 10 μm. Furthermore, an Si/SiO₂ interface exists not only in the surface, but also in the backside surface, and hence a dark current is generated in a wider region.

The main generation source of a dark current is a depleted Si/SiO₂ interface. In an interface between crystal Si of a substrate and amorphous SiO₂ of an oxidation film, dangling bonds are generated at a high surface concentration and causes the generation center at the middle of the band gap of Si. When the interface is depleted (activation energy: 0.5 eV), therefore, the dark current is generated by the generation center.

When a defect exists in an Si crystal, it functions as the generation center, and although the excitation probability is low at room temperature, also electrons which are generated beyond the band gap itself in the entire thick Si layer (activation energy: 1.12 eV) cannot be neglected.

When, in order to expose a metal pad for external wiring disposed on the surface, a through hole is formed in a silicon substrate, very high concentration dark current is generated at the inner surface of the hole. Furthermore, a p-type silicon layer is exposed from the peripheral end of a semiconductor chip, and hence also electrons which are generated from the peripheral end should be considered.

### SUMMARY OF THE INVENTION

An object of an illustrative, non-limiting embodiment of the invention is to provide a backside illuminated solid-state imaging device, which has a structure for preventing unwanted electrons that are generated in a region other than an imaging region, and that become a dark current or noise, from entering into a signal charge accumulating region, and which has a structure for lowering the grounding resistance of a high-concentration p-layer of the backside surface.

According to an aspect of the invention, there is provided a backside illuminated solid-state imaging device comprising:

a p-type semiconductor substrate;

an imaging region that receives a subject light through a back side of the p-type semiconductor substrate to accumulate a signal corresponding to an amount of the received light;

a signal reading element disposed in a front side of the p-type semiconductor substrate, the signal reading element reading out the signal from the imaging region; and

an n-well region disposed in the front side of the p-type semiconductor substrate and in a periphery of the imaging region, the n-well region being biased to a positive voltage.

The backside illuminated solid-state imaging device may further comprise a high-concentration n-type diffusion layer disposed in a surface portion of the n-well region and along a peripheral end of the p-type semiconductor substrate, the high-concentration n-type diffusion layer being biased to the positive voltage.

In the backside illuminated solid-state imaging device, the p-type semiconductor substrate may have an external connection pad hole in a region which is surrounded by the n-well region and in which the n-well region is not formed, the external connection pad hole being capable of generating a dark current.

In the backside illuminated solid-state imaging device the n-well region may be continuously disposed along an entire periphery of the imaging region in the front side of the p-type semiconductor substrate.

The backside illuminated solid-state imaging device may further comprise a p-channel transistor disposed in a surface portion of the n-well region.

The backside illuminated solid-state imaging device may further comprise a first p-well region disposed in a surface portion of the n-well region, the first p-well region being biased to a negative voltage.

In the backside illuminated solid-state imaging device, a portion of the n-well region may be formed as an n-well connection region by a same process as a charge storage region formed in the imaging region.

The backside illuminated solid-state imaging device may further comprise:

a high-concentration p-type layer disposed on a whole backside surface of the p-type semiconductor substrate;

a second p-well region disposed in a front side of a region surrounding the imaging region; and

a grounding terminal connected to a surface of the second p-well region, wherein the high-concentration p-type layer is grounded through the grounding terminal, the second p-well region and the p-type semiconductor substrate.

In the backside illuminated solid-state imaging device, the second p-well region may be disposed along a substantially entire periphery of the region surrounding the imaging region inside the n-well region.

In the backside illuminated solid-state imaging device, the p-type semiconductor substrate may have a concentration gradient of a p-type impurity therein.

According to an aspect of the invention, there is provided a backside illuminated solid-state imaging device comprising:

a p-type semiconductor substrate;

a high-concentration p-type layer disposed on a whole backside surface of the p-type semiconductor substrate;

an imaging region that receives a subject light through a back side of the p-type semiconductor substrate to accumulate a signal corresponding to an amount of the received light;

a signal reading element disposed in a front side of the p-type semiconductor substrate, the signal reading element reading out the signal from the imaging region;

a p-well region disposed in a region surrounding the imaging region in a front side the p-type semiconductor substrate; and

a grounding terminal connected to a surface of the p-well region, wherein the high-concentration p-type layer is grounded through the grounding terminal, the second p-well region and the p-type semiconductor substrate.

In the backside illuminated solid-state imaging device, the p-well region may be continuously disposed along an entire periphery of the region surrounding the imaging region.

### BRIEF DESCRIPTION OF THE DRAWINGS

The features of the invention will appear more fully upon consideration of the exemplary embodiments of the inventions, which are schematically set forth in the drawings, in which:

FIG. 1 is a plan view of a backside illuminated solid-state imaging device (CCD type) according to an exemplary embodiment of the invention, as seen from the front side;

FIG. 2 is a sectional diagram of an imaging region at positions of the line II-II of FIG. 1;

FIG. 3 is a sectional diagram of positions of the line III-III of FIG. 1;

FIG. 4 is a sectional diagram of positions of the line IV-IV of FIG. 1;

FIG. 5 is a sectional diagram of positions of the line V-V of FIG. 1;

FIG. 6 is a sectional diagram of positions of the line VI-VI of FIG. 1;

FIG. 7 is a sectional diagram of positions of the line VII-VII of FIG. 1;

FIG. 8 is a sectional diagram of positions of the line VIII-VIII of FIG. 1;

FIG. 9 is a model diagram of simulations; and

FIG. 10 is a diagram showing a potential profile of results of simulations, wherein reference numerals and signs in the drawings are set forth below.
1 p-type semiconductor substrate
2 imaging region (pixel region)
3, 4 n-well
5 high-concentration n-type diffusion layer
6 p-well
7, 8 aluminum pad
9 horizontal charge transfer path
9a embedded channel
9b transfer electrode film
10 amplifier portion
11 frame portion in which p-well is disposed
12, 16 connection pad
17 p-well
21 vertical charge transfer path
22 photodiode (n-region)
23 color filter layer
24 microlens
25 backside high-concentration p⁺⁺-layer
28 light blocking member
38 high-concentration surface p-type layer
39 high-concentration n-type layer
46 metal electrode for over drain

### DETAILED DESCRIPTION OF THE EXEMPLARY EMBODIMENTS

Although the invention will be described below with reference to the exemplary embodiment thereof, the following exemplary embodiment and its modification do not restrict the invention.

According to an exemplary embodiment of the invention, unwanted electrons which are generated in a peripheral portion of the substrate are promptly discarded through the n-well region, and holes which are generated inside the substrate are promptly discarded to the outside through the high-concentration p-layer on the back side. Therefore, a highly sensitive object image can be taken at a high S/N ratio.

Hereinafter, exemplary embodiments of the invention will be described with reference to the accompanying drawings.

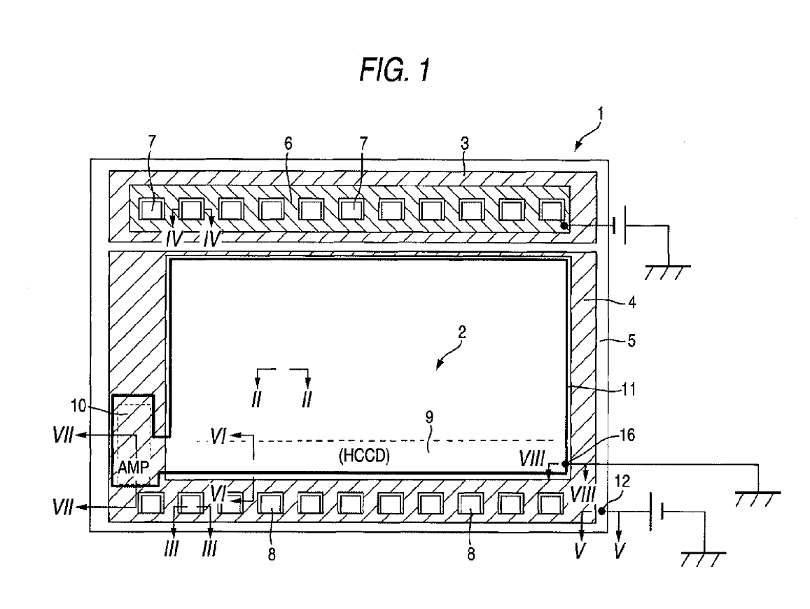

FIG. 1 is a plan view of a backside illuminated solid-state imaging device of an exemplary embodiment of the invention, as seen from the front side. A semiconductor substrate 1 forming the backside illuminated solid-state imaging device of the embodiment is of the p type. A central rectangular portion of the p-type semiconductor substrate 1 includes a pixel region 2 (an imaging region which receives field light incident through the reverse side of the sheet of FIG. 1 (the back side of the semiconductor substrate 1)), and a horizontal charge transfer path (HCCD) region 9. In the embodiment, n-well regions 3, 4 are formed in the whole region of the front side of the semiconductor substrate 1 other than the pixel region 2 and the HCCD region 9.

The illustrated n-well region 3 is an elongated rectangular region which extends along the upper edge of the semiconductor substrate 1, and the n-well region 4 is a remaining wider rectangular region. A high-concentration n-type diffusion layer which is exposed from the surface on the n-wells is formed in a boundary portion which divides the n-well regions 3, 4 from each other, and an outer periphery frame portion 5 of the semiconductor substrate 1. A positive bias voltage is applied to the n-type diffusion layer 5 through an aluminum pad 12, thereby applying a positive voltage to the n-well regions 3, 4.

A rectangular p-well region 6 which is smaller in area than the rectangular region 3 is formed on the front side of the n-well region 3 to form a double well structure. A negative bias voltage is applied to the p-well region 6. Aluminum pads 7 are formed in a portion where the p-well region 6 is formed.

In the illustrated embodiment, aluminum pads 8 are formed in a portion of the n-well region 4 which extends along the lower edge of the substrate. The horizontal charge transfer path (HCCD) region 9 is disposed in the boundary portion between the pixel region 2 which is surrounded by the n-well region 4, and the n-well region 4 which extends along the lower edge of the pixel region. An amplifier (AMP) which converts the charge amount of signal charges transferred through the HCCD to a voltage value signal is formed in a rectangular region 10 on the output side of the HCCD.

In the frame portion indicated by a thick line 11 which is indicated in FIG. 1, and which surrounds the pixel region 2, the HCCD forming region 93 and the amplifier region 10, a p-well region 17 which will be described later, and which is shown in FIG. 6 is formed. The p-well region 17 is grounded through a pad 16, thereby grounding a high-concentration p-layer (p⁺⁺layer) 25 which will be described later, and which is on the backside surface.

A large area of the n-well region 4 is exposed from the front side in the left and right sides of the pixel region 2 shown in FIG. 1. In the case where elements such as transistors necessary for the solid-state imaging device are to be formed, a p-well region is formed in the front side of the n-well region to form a double well structure, transistor elements and the like are formed on the p-well region, or p-channel transistor elements are formed in the surface of the n-well region, and a protective circuit, the amplifier (AMP), and the like are formed.

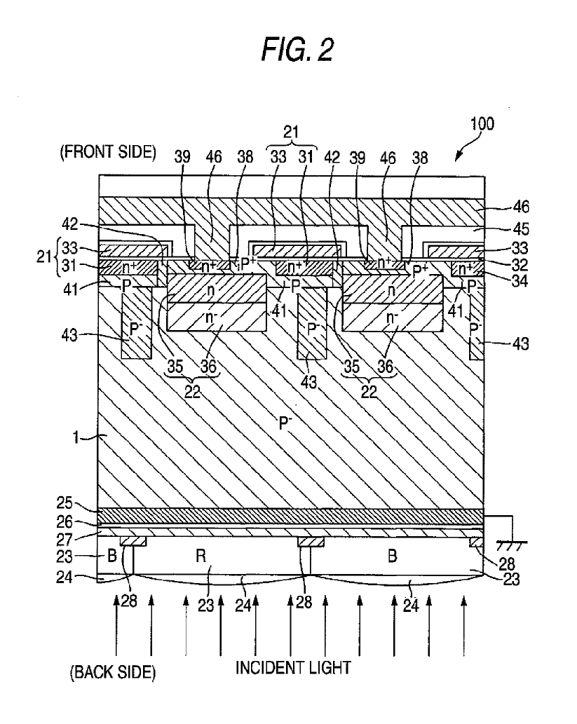

FIG. 2 is a sectional diagram of positions of the line II-II of FIG. 1 and the pixel region. The backside illuminated solid-state imaging device 100 of the embodiment is an interline CCD. Vertical charge transfer paths (VCCDs) 21 and photodiodes 22 are formed in the front side of the p-type semiconductor substrate 1, and a color filter (red (R), green (G), and blue (B)) layer 23 and microlenses 24 are stacked on the back side.

The high-concentration p⁺⁺-layer 25 is formed in a surface portion of the back side of the semiconductor substrate 1, and grounded through the p-well region 17 which has been described with reference to FIG. 1. An insulating layer 26 made of silicon oxide, silicon nitride, or the like which is transparent to incident light is stacked on the high-concentration p⁺⁺-layer 25. A high-refractive index layer 27 made of silicon nitride, a film of diamond structured carbon, or the like which is transparent to incident light is stacked on the high-concentration p⁺⁺-layer. The color filter layer 23 and the microlens (top-lens) layer 24 are sequentially stacked on the high-refractive index layer. Each of the microlenses 24 is formed so as to focus on the center of the corresponding photodiode 22 disposed at a position facing thereto.

The color filter layer 23 is partitioned in the unit of a pixel (photodiode). A light blocking member 28 for preventing color mixture from occurring between pixels is disposed between adjacent zones of the color filter layer 23 on the side of the semiconductor substrate 1.

Each of the vertical charge transfer paths (VCCDs) 21 which are formed in the front side of the semiconductor substrate 1 is configured by: an embedded channel 31 formed by an n⁺-layer; and a transfer electrode film 33 which is stacked via a gate insulating layer 32 that is formed on the outermost surface of the front side of the semiconductor substrate 1, and that is configured by a silicon oxide film or an insulating film having the ONO (oxide film-nitride film-oxide film) structure.

The vertical charge transfer paths 21 are formed so as to extend in a direction perpendicular to the direction along which the horizontal charge transfer path (HCCD) shown in FIG. 1 extends, and in a plural number. Between adjacent vertical charge transfer paths 21, plural photodiodes 22 are formed at a pitch in the direction along the vertical charge transfer paths 21.

In the embodiment, each of the photodiodes 22 is configured by an n-layer 35 which is formed in the front side of the p-type semiconductor substrate 1, and an n⁻-layer 36 which is formed under the n-layer 35. A p-type high-concentration (p⁺) surface layer 38 for suppressing a dark current is formed on a surface portion of the n-layer 35, and an n⁺-layer 39 functioning as a contact portion is formed in a middle surface portion of the surface layer 38.

A p-layer 41 which is higher in p-concentration than the substrate 1 is formed under the embedded channel (n⁺-layer) 31 of the vertical charge transfer path 21. A p⁺-region 42 which serves as an element separation region is formed between the n- and p-layers 31, 41, and the photodiode 22 which is adjacent on the right side in the illustrated embodiment. A p⁻-region 43 which is higher in concentration than tile semiconductor substrate 1 is disposed under each p-layer 41 to separate adjacent photodiodes 22. The p⁻-regions 43 are disposed in portions corresponding to the above-described pixel separating portions or the light blocking members 28.

The p-layer 41 which is formed under the embedded channel 31 of the vertical charge transfer path 21 extends to an end portion of the surface of the n-layer 35 which is adjacent on the left side in the illustrated embodiment. The p⁺-surface layer 38 in the end portion is retracted from the position of the right end face of the n-layer 35. The left end face of the transfer electrode film 33 extends so as to overlap with that of the p-layer 41, and the n-layer 35 and surface end portions of the transfer electrode film 33 and the p-layer 41 slightly overlap with each other.

This overlapping configuration is enabled because, in the backside illuminated type, there is a margin in area in the front side of the semiconductor substrate 1. In the front side illuminated type, there is no margin in area, and hence an end portion of a transfer electrode film can extend only to a position coincident with an end portion of a photodiode, and a p-layer cannot be interposed therebetween.

When the p-layer 41 is interposed between the transfer electrode film 33 and the n-layer 35 as in the embodiment, a readout voltage to be applied to the transfer electrode film (functioning also as a readout electrode) 33 can be lowered, and the power consumption of a CCD solid-state imaging device can be reduced.

The transfer electrode film 33 made of a polysilicon film or the like is formed on the insulating layer 32 formed on the outermost surface of the semiconductor substrate 1, and an insulating layer 45 is stacked thereon. Then, an opening is formed in the insulating layers 32, 45 on the n⁺-layer 39, and a metal electrode 46 is stacked on the insulating layer 45, thereby contacting the n⁺-layer 39 with the electrode 46. The electrode 46 functions as an overflow drain of the backside illuminated solid-state imaging device 100.

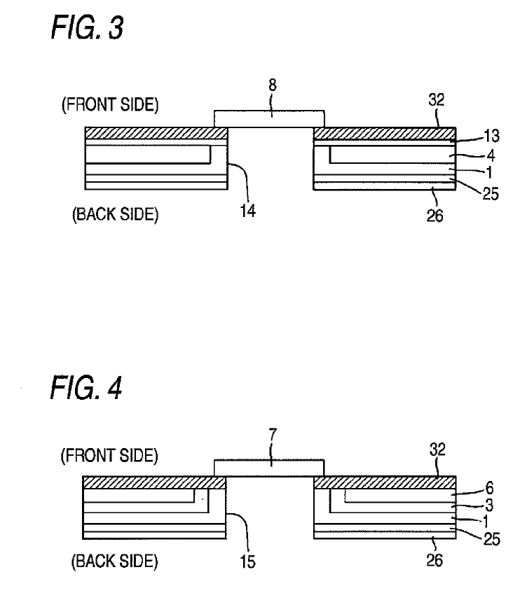

FIG. 3 is a sectional diagram of positions of the line III-III of FIG. 1. The n-well region 4 is formed in the front side of the p-type semiconductor substrate 1, an inversion preventing layer 13 is formed on the surface of the n-well region 4, and the thick oxide film 32 is formed at an increased thickness on the inversion preventing layer 13. The high-concentration p⁺⁺-layer 25 is formed in the back side of the semiconductor substrate 1, and the insulating layer 26 is disposed on the surface of the back side.

The aluminum pad 8 for external wiring is disposed on the front side, and a through hole 14 is opened from the back side so as to reach the aluminum pad 8. The through hole 14 is disposed at a position where the n-well region 4 is not exposed to the inner peripheral surface.

FIG. 4 is a sectional diagram of positions of the line IV-IV of FIG. 1. The n-well region 3 (simultaneously with and continuous to the n-well region 4) is formed in the front side of the p-type semiconductor substrate 1, and the p-well region 6 is formed in the front side of the n-well region 3. The thick oxide film 32 is formed on the outermost surface, and the aluminum pad 7 is formed on the film. The high-concentration p⁺⁺-layer 25 is formed in the back side of the semiconductor substrate 1, and the insulating layer 26 is disposed on the layer 25.

A through hole 15 is opened from the rear face side so as to reach the aluminum pad 7 for wiring. The through hole 15 is disposed at a position where the n-well 3 is not exposed to the inner peripheral surface of the through hole 15.

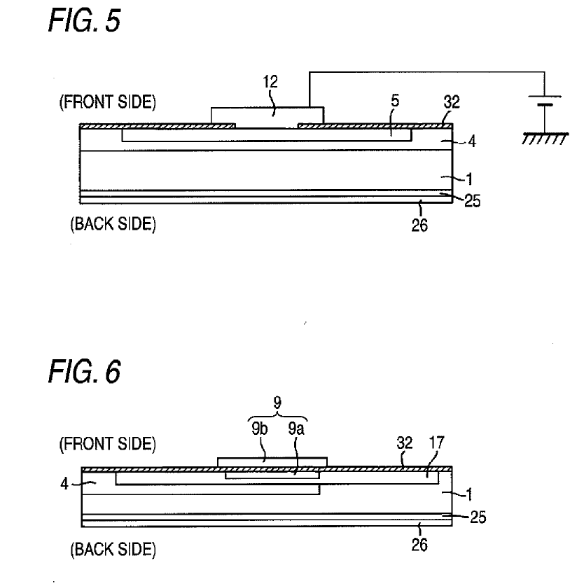

FIG. 5 is a sectional diagram of positions of the line V-V of FIG. 1. The n-well region 4 is formed in the front side of the p-type semiconductor substrate 1, the high-concentration n⁺-type diffusion layer 5 is formed in a region of the surface of the n-well region 4, and the oxide film 32 is formed at a reduced thickness on the layer 5. An opening is disposed in the oxide film 32 on the n⁺-type diffusion layer 5, and the aluminum pad 12 is disposed above the opening. The positive bias voltage shown in FIG. 1 is applied to the aluminum pad 12. The p⁺⁺-layer 25 is formed in the back side of the p-type semiconductor substrate 1, and the insulating layer 26 is disposed on the layer 25.

FIG. 6 is a sectional diagram of positions of the line VI-VI of FIG. 1, and taken along the width direction of the horizontal charge transfer path (HCCD) 9. The p⁺⁺-layer 25 is formed in the back side of the semiconductor substrate 1, and the insulating layer 26 is formed on the layer 25.

The n-well region 4 is formed in the front side of the p-type semiconductor substrate 1. The n-well region 4 is disposed in a range from a portion immediately below the horizontal charge transfer path 9 to the left side of the path, and not disposed on the right side, i.e., the side of the imaging region 2. The p-well region 17 is formed in the front side of the semiconductor substrate 1. The p-well region is formed in the same production step as the p-well region 6 of FIG. 4.

An n-layer 9a which will be formed as an embedded channel of the horizontal charge transfer path 9 is formed in the front side of the p-well region, the oxide film 32 is formed at a reduced thickness on the surface of the semiconductor substrate 1, and a transfer electrode film 9b of the horizontal charge transfer path 9 is formed on the film by polysilicon or the like.

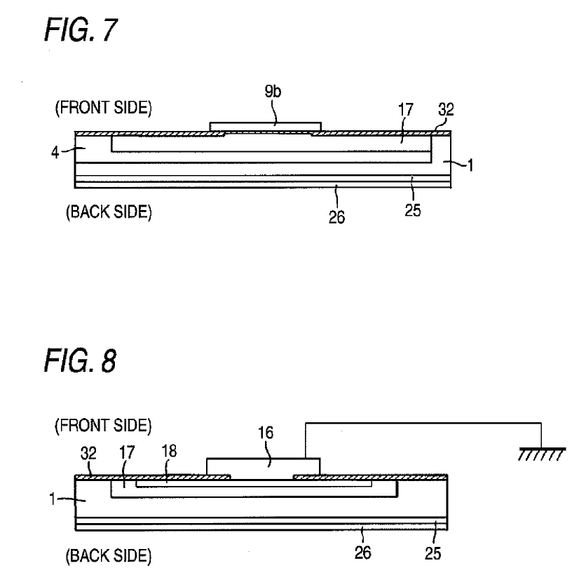

FIG. 7 is a sectional diagram of positions of the line VII-VII of FIG. 1, and taken along the width direction of the gate of the amplifier portion 10. The p⁺⁺-layer 25 is formed in the back side of the p-type semiconductor substrate 1, and the insulating layer 26 is formed on the layer 25.

The n-well region 4 is formed in the front side of the p-type semiconductor substrate 1, the p-well region 17 is formed on the n-well region 4, and the oxide film 32 is formed on the p-well region 17. The gate electrode film 9b is formed on the oxide film 32 by polysilicon or the like. The oxide film 32 immediately below the gate electrode 9b is formed at a reduced thickness.

FIG. 8 is a sectional diagram of positions of the line VIII-VIII of FIG. 1, and taken in the portion where the p-well region 17 is disposed. The p⁺⁺-layer 25 is formed in the back side of the p-type semiconductor substrate 1, and the insulating layer 26 is formed on the layer 25.

The p-well region 17 is formed in the front side of the p-type semiconductor substrate 1, a high-concentration p-layer 18 is formed as a contact portion on the p-well region 17, and the oxide film 32 is formed at a reduced thickness on the surface of the semiconductor substrate 1. The oxide film 32 on the contact portion 18 is removed away, and the aluminum pad 16 is disposed thereon. The aluminum pad 16 is connected to the ground.

Preferably, the above-described n-well regions 3, 4 are produced together with the production of the n-regions 35, 36 constituting the photodiode 22, and the like. The number of masks required in the production, and that of production steps are reduced. Therefore, the production cost can be lowered. Preferably, the structure shown in FIG. 8 is formed in the entire periphery surrounding the imaging region 2 and the HCCD region 9.

In the case where an object image is to be taken by the thus configured backside illuminated solid-state imaging device 100, light incident from an object field enters through the back side of the semiconductor substrate 1. The incident light is converged by the microlens 24 of FIG. 2, passed through the color filter layer 23, and enters into the semiconductor substrate 1.

When light converged by the microlens 24 is incident into the semiconductor substrate 1, the incident light advances in the direction to the photodiode 22 corresponding to the microlens 24 and the color filter 23 while being converged, and optically absorbed by the semiconductor substrate 1 to be photoelectrically converted to generate pairs of electrons and holes.

In the backside illuminated solid-state imaging device 100, the distance between the back side of the semiconductor substrate 1 and the n-region 22 constituting the photodiode is set to about 9 μm. During the period when the incident light reaches the n⁺-region, i.e., the charge transfer path 21 disposed in the front side of the semiconductor substrate 1, all of the light is absorbed by the substrate 1 to be photoelectrically converted. Accordingly, it is not required to block light from entering the vertical charge transfer paths 21.

In each pixel, electrons generated in the photoelectric converting region (the region extending from the p⁺⁺-layer 25 to the n-region 35) are accumulated in the n-region 35 in the pixel, and, when the readout voltage is applied to the transfer electrode film 33 functioning also as the readout electrode, read out from the n-region 35 to the embedded channel 31 which is adjacent on the right side in the example shown in FIG. 2. Thereafter, the electrons are transferred to the horizontal charge transfer path (HCCD) 9 along the vertical charge transfer path 21, and further transferred to the amplifier 10 along the horizontal charge transfer path 9. The amplifier 10 outputs the voltage value signal corresponding to the signal charge amount, as a taken-image signal.

When holes generated in the photoelectric converting region in the p-type semiconductor substrate 1 wander in the substrate 1, uneven sweeping of holes occurs between a middle portion of the imaging region 2 of FIG. 1 and a peripheral portion, and a difference is caused between pixel characteristics. In the backside illuminated solid-state imaging device 100 of the embodiment, holes generated in the semiconductor substrate 1 can be absorbed by the p⁺⁺-layer 25 which is disposed in a substantially whole region of the back side surface, and the absorbed holes can be stably swept away to the ground in the following manner.

As described with reference to FIGS. 6, 7, and 8, the p-well region 17 which is in contact with the p-type semiconductor substrate 1 is disposed with a required width in the peripheries of the imaging region 2, the horizontal charge transfer path 9, and the amplifier portion 10, and the total area of the p-well region 17 is large.

The resistance per unit area between the p-well region 17 disposed in the front side and the high-concentration p⁺⁺-layer 25 in the back side is high. However, the combined resistance between the p-well region 17 and the p⁺⁺-layer 25 is sufficiently low because the total area of the p-well region 17 is large. When the p-well region 17 is grounded, the p⁺⁺-layer 25 can be connected with a low resistance to the ground.

The holes generated in the imaging region 2 of the semiconductor substrate 1 are promptly attracted to the p⁺⁺-layer 25, moved toward the p-well region 17 shown in FIG. 8 by the frame portion 11 which is disposed so as to surround the imaging region 2, and stably swept away to the ground through the pad 16.

When the semiconductor substrate 1 shown in FIG. 8 is configured as a p-type substrate having a concentration gradient in which the p-type impurity concentration is higher as further advancing toward the back side, the resistance is further lowered, so that holes can be swept away more promptly.

In the backside illuminated solid-state imaging device 100, a wide Si/SiO₂ interface exists also in the back side, and this functions as a dark current source. In the embodiment, the p⁺⁺-layer 25 is disposed in the whole region of the back side surface. Therefore, a dark current generated in the Si/SiO₂ interface (the interface between the layers 25, 26) is recombined with holes in the p⁺⁺-layer 25 to disappear, with the result that the dark current does not flow toward the n-region 35, and does not cause noise. Furthermore, also a dark current generated in the Si/SiO₂ interface in the front side of the n-region 35 is recombined with holes in the p⁺-surface layer 38 to disappear, and is not mixed with the signal charge of the n-region 35.

Electrons generated in the peripheral portion of the imaging region 2 should be blocked so as not to enter the imaging region 2. In the example shown in FIG. 1, in order to expose the metal pads 7, 8 of the front side from the back side, the through holes 14, 15 (FIGS. 3 and 4) are opened in the semiconductor substrate 1. However, the inner peripheral surfaces of the through holes 14, 15 function as dark high-density current sources. The p-type silicon layer is exposed from the end surface in the periphery of the semiconductor substrate (chip) 1, and hence electrons are generated also from the end surface.

In a backside illuminated image sensor employing a p-type silicon substrate, when unwanted electrons generated in the substrate wander in the substrate, and enter the pixel region (imaging region) to be accumulated in photodiodes, the electrons become noise components. Therefore, it is necessary to dispose a drain structure for discarding unwanted electrons generated in the substrate to the outside. In the embodiment, the n-well regions 3, 4 and the n-type diffusion layer 5 constitute the drain structure.

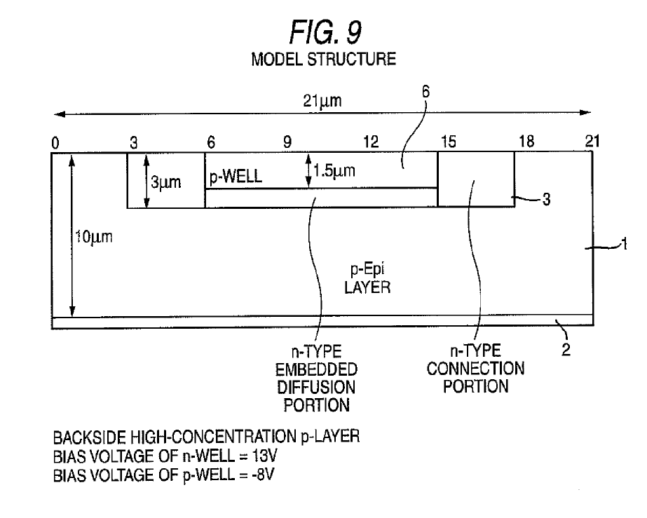

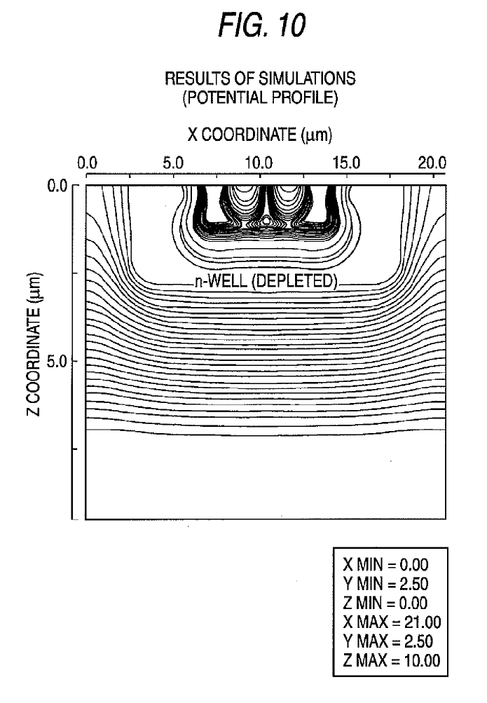

FIG. 9 is a diagram illustrating the drain structure formed by an n-well. In the p-type semiconductor substrate 1, a high-concentration n-type embedded diffusion portion is formed in a planar manner, and a thin n-type connection portion (n-well connection portion) is formed in the periphery of the n-type embedded diffusion portion so that the n-type connection portion reaches the surface of the substrate 1, thereby forming the n-well 3. The positive bias voltage is externally applied to the portion where the n-type layer is formed to reach the surface. In order to reduce the number of production steps, preferably, the n-well connecting portion shown in FIG. 9 is formed by the same process as the n-regions 35, 36 of FIG. 2. The high-concentration p-layer 25 is formed in the back side of the n-well p-type semiconductor substrate 1, and, for example, the drain and source of a transistor are formed in the surface of the p-well region 6 formed in the central surface portion of the n-well 3.

FIG. 10 is a view showing results of simulations in which a positive voltage of 13 V is applied to the n-well 3, a negative voltage of −8 V to the p-well 6, a voltage of 0 V to the backside high-concentration p-layer 25, and a voltage of +13 V to the drain and the source. It will be seen that the n-well 3 enables an extent of the substrate to a considerably deep portion to be depleted.

In the backside illuminated solid-state imaging device of the embodiment, portions where a device is produced, excluding the imaging region 2, such as the peripheries of the pads 7, 8, and under sides of the aluminum wiring, the HCCD 9, and the amplifier 10 are formed so as to have a double well structure where an n-well region is disposed. In the other portion, an n-well region which is exposed to the surface is disposed, so that the depleted region is made wider. Therefore, electrons generated in the above-mentioned dark current sources are attracted to the n-wells, and then discarded to the outside through the high-concentration n-type diffusion layer 5 which has been described with FIGS. 1 and 5.

In the embodiment, furthermore, the n-type diffusion layer 5 for discarding unwanted electrons to the outside is disposed in the vicinity of the dark current source, and hence the electrons can be discarded more promptly. Specifically, the n-type diffusion layer 5 is disposed in a frame-like manner along the peripheral end face of the chip which functions as a dark high-density current source, and along the rows of the pads 7, 8 which function as dark high-density current sources. Therefore, a dark current generated from the inner peripheral faces of the through holes for the pads flows into the n-type diffusion layer 5 which is the nearest portion, before the dark current enters into the imaging region 2, and then are discarded to the outside.

In the above-described backside illuminated solid-state imaging device, the signal reading circuit is of the CCD type. It is a matter of course that the above-described embodiment can be applied also to circuits of the CMOS type and the like.

In the backside illuminated solid-state imaging device of the invention, a dark current can be prevented from being mixed with signal charges. Therefore, the device is useful as a solid-state imaging device in which the S/N ratio is high, the sensitivity is high, and the efficiency is high.

What is claimed is:

1. A backside illuminated solid-state imaging device comprising:
a p-type semiconductor substrate;
an imaging region that receives a subject light through a back side of the p-type semiconductor substrate to accumulate a signal corresponding to an amount of the received light;
a signal reading element disposed in a front side of the p-type semiconductor substrate, the signal reading element reading out the signal from the imaging region; and
an n-well region disposed in the front side of the p-type semiconductor substrate and in a periphery of the imaging region, the n-well region being biased to a positive voltage.

2. The backside illuminated solid-state imaging device according to claim 1, further comprising a high-concentration n-type diffusion layer disposed in a surface portion of the n-well region and along a peripheral end of the p-type semiconductor substrate, the high-concentration n-type diffusion layer being biased to the positive voltage.

3. The backside illuminated solid-state imaging device according to claim 1, wherein the p-type semiconductor substrate has an external connection pad hole in a region which is surrounded by the n-well region and in which the n-well region is not formed, the external connection pad hole being capable of generating a dark current.

4. The backside illuminated solid-state imaging device according to claim 1, wherein the n-well region is continuously disposed along an entire periphery of the imaging region in the front side of the p-type semiconductor substrate.

5. The backside illuminated solid-state imaging device according to claim 1, further comprising a p-channel transistor disposed in a surface portion of the n-well region.

6. The backside illuminated solid-state imaging device according to claim 1, further comprising a first p-well region disposed in a surface portion of the n-well region, the first p-well region being biased to a negative voltage.

7. The backside illuminated solid-state imaging device according to claim 1, wherein a portion of the n-well region is formed as an n-well connection region by a same process as a charge storage region formed in the imaging region.

8. The backside illuminated solid-state imaging device according to claim 1, farther comprising:
a high-concentration p-type layer disposed on a whole backside surface of the p-type semiconductor substrate;
a second p-well region disposed in a front side of a region surrounding the imaging region; and
a grounding terminal connected to a surface of the second p-well region, wherein the high-concentration p-type layer is grounded through the grounding terminal, the second p-well region and the p-type semiconductor substrate.

9. The backside illuminated solid-state imaging device according to claim 8, wherein the second p-well region is disposed along a substantially entire periphery of the region surrounding the imaging region inside the n-well region.

10. The backside illuminated solid-state imaging device according to claim 8, wherein the p-type semiconductor substrate has a concentration gradient of a p-type impurity therein.

11. A backside illuminated solid-state imaging device comprising:
a p-type semiconductor substrate;
a high-concentration p-type layer disposed on a whole backside surface of the p-type semiconductor substrate;
an imaging region that receives a subject light through a back side of the p-type semiconductor substrate to accumulate a signal corresponding to an amount of the received light;
a signal reading element disposed in a front side of the p-type semiconductor substrate, the signal reading element reading out the signal from the imaging region;
a p-well region disposed in a region surrounding the imaging region in a front side the p-type semiconductor substrate; and
a grounding terminal connected to a surface of the p-well region, wherein the high-concentration p-type layer is grounded through the grounding terminal, the second p-well region and the p-type semiconductor substrate.

12. The backside illuminated solid-state imaging device according to claim 11, wherein the p-well region is continuously disposed along an entire periphery of the region surrounding the imaging region.
